(19) United States
(12) Patent Application Publication
(10) Pub. No.: US 2005/0258550 A1
(43) Pub. Date: Nov. 24, 2005

(54) Circuit board and semiconductor device using the same

(76) Inventors: Toshiaki Morita, Hitachi (JP); Kazuhiro Suzuki, Mito (JP); Hisayuki Imamura, Fukaya (JP); Junichi Watanabe, Kumagaya (JP); Mitsuaki Chiba, Hitachinaka (JP)

Correspondence Address: DICKSTEIN SHAPIRO MORIN & OSHINSKY LLP, 2101 L Street, NW, Washington, DC, 20037, US

(21) Appl. No.: 11/066,200

(22) Filed: Feb. 25, 2005

(30) Foreign Application Priority Data
May 18, 2004 (JP) 2004-148002

(51) Int. Cl. H01L 23/52

(52) U.S. Cl. 257/784

(57) ABSTRACT

There is provided a thinner high frequency power module structure having reduced the mounting area. An insulated board is provided with a composite metal board in which the Cu₂O powder particles are dispersed into a matrix metal (Cu) (amount of addition of Cu₂O: 20 vol %; thermal expansion coefficient: 10.0 ppm/° C.; thermal conductivity: 280 W/m•K; thickness: 1 mm; size: 42.4×85 mm), a silicon nitride board (thermal expansion coefficient: 3.4 ppm/° C.; thermal conductivity: 90 W/m•K; thickness: 0.3 mm; size: 30×50 mm) deposited with Ag-system bonding metal layer to one principal surface of the composite metal board, and a wiring metal board formed of copper or copper alloy provided to the other principal surface of the ceramics insulated board. For example, the bonding metal layer is adjusted in the thickness to 50 μm, while the wiring metal board is also adjusted in the thickness to 0.4 mm. In the integrated board of the wiring and heat radiating boards, the Ni plating layer (thickness: 6 μm, not illustrated) is formed with the non-electrolyte wet plating process to the surface metal layer of the wiring metal board and composite metal board. This Ni plating layer is formed to the wiring metal boards in order to attain the solder bondability to mount the semiconductor base material with the brazing method and to enhance the wire bondability of the wiring metal board. Moreover, this Ni plating layer effectively prevents denaturation of the internal side by shutting off from the external atmosphere.

This application is based on the Japanese Patent application No. 2004-148002, filed on May 18^{th}, 2004, all the contents of which is incorporated in this application by reference.

### FIELD OF THE INVENTION

The present invention relates to an insulated semiconductor device and particularly to an insulated semiconductor device in the structure using an insulating member as a bottom cover of a case.

### BACKGROUND OF THE INVENTION

A semiconductor device having the structure in which a semiconductor element base material is mounted on a metal supporting member has a merit that a degree of freedom for application into a circuit is high because all electrodes can be guided to the external side under the condition electrically insulated from all package members including the metal supporting member. In the example of structure where a pair of main electrodes is floated from the ground potential, for example, mounting of a semiconductor device can be done easily because a package can be fixed to the ground potential portion without relation to electrode potential.

For safe and stable operations of a semiconductor element, heat generated by operations of the semiconductor device must be effectively radiated to the outside of package. Such heat radiation is generally conducted by transferring the heat to the atmosphere through each member bonded to a semiconductor element base material as a heat generating source. In the semiconductor device, an insulator, a bonding material layer used for the part for bonding the semiconductor base material and a metal supporting member or the like are included in this heat transfer route.

Moreover, the higher the power treated by the circuit including the semiconductor device becomes and the higher the required reliability (stability in aging, humidity proof characteristic, and heat resistance or the like) becomes, the more the higher insulation property is required. Heat resistance described above include the heat resistance when the ambient temperature of the semiconductor device rises due to the external causes and the heat resistance when the semiconductor device processes the higher electrical power and a large mount of heat is generated from the semiconductor base material.

Meanwhile, since a set of electrical circuits including a semiconductor element base material is generally built into a semiconductor device, at least a part of the circuits must be electrically insulated from a supporting member. For example, there is proposed a power module in which an assembly mounted to an AlN ceramics board (hereinafter, referred to as a “copper clad AlN board”) in which the copper plates are joined to both surfaces of a Si chip is integrated to a copper supporting member with soldering process (for example, refer to the document, “DBC Board for Semiconductor and Communication”, pp 65 to 69 of Electronic Material (Vol. 44, No. 5) (1989).

In this non-patent document, a copper clad AlN board has characteristics of high heat conductivity (190 W/m•K), low expansion coefficient (4.3 ppm/° C.) and high insulation property (1015 Ω•cm) or the like of AlN and characteristics of high heat conductivity (403 W/m•K) and high electrical conductivity (1.7×10−6 Ω•cm) or the like of copper. Accordingly, this copper clad AlN board may be effectively used to obtain a module device which assures excellent heat radiating property and higher reliability by mounting, with direct soldering process, a semiconductor element base material for power (Si: 3.5 ppm/° C.) which assures higher current density and excellent heat radiation.

The copper clad AlN board generally plays a role of improving heat radiation effect by electrically insulating, from a copper supporting member, a semiconductor element base material mounted with the soldering process to the board or an electrical circuit formed to such base material and by forming a heat flowing path reaching a cooling fin from the semiconductor base material. Moreover, when the copper clad AlN board is used, the number of components and number of assembling processes of the power module can be reduced because the semiconductor base material having small thermal expansion coefficient can be mounted in direct without use of a thermal expansion buffer material (for example, Mo and W).

Moreover, there is disclosed (for example, refer to JP-B No. 26174/1995) a semiconductor module device in which an assembly mounting a thyristor chip on an alumina board is mounted to a supporting member formed of a compound material wherein the SiC ceramic powder is dispersed into Al or Al alloy (hereinafter, referred to as “Al/SiC compound material”).

In JP-B No. 26174/1995, since the alumina board (7.5 ppm/° C.) is mounted to the Al/SiC compound material supporting member (6.7 to 14 ppm/° C.) having the thermal expansion coefficient similar to that of the alumina board, structure of the connecting portion of these members has excellent reliability and effectively prevents deterioration in heat radiation characteristic.

Moreover, there is disclosed a structure of a ceramic circuit board with a heat sink (for example, refer to JP-A No. 65075/1998) in which a circuit board in which an Al plate for circuit wiring and an Al plate for thermal diffusion are respectively bonded to both surfaces of the ceramic board via the Al—Si system brazing material and the heat sink formed of the Al/AiC composite material are joined via an Al alloy.

According to JP-A No. 65075/1998, the number of manufacturing steps of a power module can be reduced because crack of ceramic board is prevented since the Al plates having small deformation resistance are joined to both surfaces and a heat sink is previously joined to the Al plate for heat diffusion via an Al alloy in the heat sink.

Moreover, the Al/SiC compound material is manufactured by providing adjacently a ceramic board and a porous perform formed of SiC powder and then impregnating the fused Al into the porous perform. In addition, a circuit board is also disclosed, in which the Al/SiC compound material and the ceramics board are integrated with the fused Al and an Al circuit is formed on the surface of the ceramics board (for example, refer to JP-A No. 277953/2000). Thereby, a low cost circuit board may be obtained.

In general, as described in the document, “DBC Board for Semiconductor and Communication”, pp 65 to 69 of Electronic Material (Vol. 44, No. 5) (1989), a copper clad AlN board on which a semiconductor base material is soldered is integrated with a copper supporting member with the similar soldering process. Here, the reason why a copper plate having the higher thermal conductivity is used as the supporting member is that the heat radiation effect can be raised by widening the flow of heat transmitted from the copper clad AlN board. In this case, since difference in the thermal expansion coefficient between the cupper supporting member and the copper clad AlN board is large, reliability is easily deteriorated because of fracture of solder layer, shutdown of heat flowing path, and destruction of circuit board, etc. In more practical, here rise the problems (1) to (3) described below.

(1) Thermal Stress, Strain, Damage of Insulated Board (Circuit Board)

Since the thermal expansion coefficients of copper clad AlN board and copper supporting member are different, a residual thermal stress or thermal strain is generated in the integrated substance of these board and member. The copper clad AlN board and copper supporting member are subjected, at the time of integration thereof, to the heat treatment process that these are cooled, at the time of integration, up to the room temperature after once heated up to the temperature higher than the fusing point of the solder material. In this case, each member is contracted in accordance with the intrinsic thermal expansion coefficient of each member while it is fixed with each other at the solidifying point of solder material. Accordingly, thermal stress or thermal strain is left and deformation is also generated at the bonding point.

In general, a size of semiconductor base material for power is large and a plurality of semiconductor base materials and the other elements are also mounted to a semiconductor device. Therefore, the area of circuit board and brazing portion becomes large. Accordingly, residual thermal stress and thermal strain become large and deformation of each member is accelerated easily. Thermal stress during operation is repeated applied to the semiconductor device and if this thermal stress is superimposed to the residual thermal stress or thermal strain, the heat flowing path is shut down due to fatigue fracture of the solder layer (#2 solder layer described later, particularly) and breakdown occurs in the ceramics insulated board having brittle property in the mechanical structure. Such event not only impedes the normal operation of a semiconductor device but also results in a problem in safety particularly represented by breakdown of the circuit board.

(2) Thermal Engagement by Curvature and Damage of Circuit Board

Since the thermal expansion coefficients of the copper clad AlN board and copper supporting member are different, such integrated substance generates a curvature. If curvature is generated in a semiconductor device, it is difficult to uniformly supply a thermal conductive grease at the time of mounting a semiconductor device to a cooling fin. As a result, successful thermal engagement cannot be attained between the copper supporting member and the cooling fin and thereby heat radiating characteristic of this path is deteriorated, making it difficult to normally operate the semiconductor device. Moreover, when the semiconductor device is mounted on the cooling fin through the screwing, a new external force is applied thereto, easily generating damage of circuit board.

(3) Problem in the Number of Assembling Processes and Difficulty in Lead-Free Soldering

Since the process to solder the semiconductor base material and the copper clad AlN board (forming of the #1 solder) and the integrating process of the copper clad AlN board and the copper supporting member by the similar soldering (forming of the #2 solder) are necessary, the number of assembling processes of the semiconductor device increases. Moreover, in the process to form the #1 solder layer and the #2 solder layer, temperature hierarchical property (solder materials having different melting points) is necessary. However, it is difficult to obtain sufficient temperature hierarchical property from combination of the existing lead-free solder materials.

The supporting member described in JP-B No. 26174/1995 described above is a composite material in which the SiC powder is dispersed into an Al matrix metal by impregnating a melted metal mainly formed of Al into a porous perform formed of the SiC ceramics powder (hereinafter, referred to as “Al/SiC”). Since the thermal expansion coefficient of this member may be controlled with amount of addition of the SiC powder, it is possible to clear the problems described in the items (1) and (2). However, a problem of the item (3) is still left unsolved for the assembling of the semiconductor device because both processes to form the #1 solder and #2 solder layer are still necessary. Moreover, a problem that cost becomes higher is still left because the alumina insulating member and the Al/SiC supporting member are manufactured with different processes.

The semiconductor device using a circuit board with a heat sink based on JP-A No. 65075/1998 previously integrates a circuit board and a supporting member. Therefore, subsequent assembling process thereof is simplified. However, the circuit board provided with a heat sink can be attained through the processes that the Al clad AlN board and Al/SiC heat sink which are manufactured respectively with individual processes are laminated and are heated under the evacuated condition while these are pressurized. In these processes, much cost is required and it finally impedes reduction in cost of the semiconductor device.

Moreover, the Al clad AlN board manufactured previously and an oxide substance formed on the surface of the Al/SiC heat sink are left at the interface after the junction, and therefore connection property and reliability of this interface is easily damaged.

A ceramics circuit board based on the technology described in JP-A No. 277953/2000 is formed through direct integration of an Al/SiC base board and a ceramics circuit board, the subsequent power module assembling process is simplified. In addition, manufacture of Al/SiC and wiring to the ceramics circuit board are implemented with the same process as integration by supplying the melted Al alloy to the predetermined dies.

Therefore, the ceramics circuit board is probably manufactured in comparatively lower cost and is also finally expected in such a point that the semiconductor device may be attained in lower cost. However, in the case of this structure, since the Al/SiC base board and ceramics circuit board are integrated in direct under a comparatively higher temperature, stress, strain, and deformation by curvature are easily generated in the integrated boards, resulting in the problem described in the items (1) and (2). The patent documents and non-patent document described above do not yet disclose solutions of such problems and the optimum structure for avoiding failures particularly in the manufacturing and operating condition of the semiconductor device.

### SUMMARY OF THE INVENTION

An object of the present invention is to provide a highly reliable and low cost semiconductor device which can alleviate thermal stress or thermal strain generated during manufacture and operation and can also eliminate possibility in deformation, denaturation, and breakdown of each member.

The present invention relates to a circuit board and a semiconductor device using the same circuit board characterized in that a semiconductor element is deposited a circuit wiring board formed of copper or copper alloy provided on one surface of a ceramics board, the other surface of the ceramics board is deposited to a supporting member (heat radiating wiring board) via a bonding metal layer, the supporting member (heat radiating board) is constituted of a metal board consisting of copper or copper alloy, and the thermal expansion coefficient of the metal supporting member (heat radiating wiring board) formed of copper or copper alloy is smaller than that of copper or copper alloy wiring layer.

The semiconductor device of the present invention which has achieved the objects described above is characterized in that a case is formed of a resin case provided with an aperture and a circuit board mounted to the aperture and the circuit board also forms a bottom cover of the case.

The structure described above can maintain the excellent heat radiation property and reliability and moreover is capable of making contribution to acquisition of a low cost semiconductor device. The ceramics board described above is also characterized in that it is formed of at least a kind of material selected from a group of silicon nitride, aluminum nitride, and alumina.

In addition, the semiconductor device of the present invention is characterized in including a composite metal board or/and wiring metal board which is covered at the surface thereof with a corrosion proof metal material, preferably with at least a kind of metal selected from Ni, Sn, Ag, Au, Pt, Pd, Zn, and Cu.

As described above, the present invention can provide a low cost semiconductor device which can alleviate thermal stress or thermal strain which is generated during manufacture or operation, provides least possibility of deformation, denaturation, and breakdown of each member, and assures excellent heat radiation property and higher reliability.

In more practical, a thermal resistance of 0.4° C./W or less can be attained and excellent flatness with less curvature can be acquired to realize electrically stable operation by selecting copper or copper alloy for the wiring metal board and using a copper system material having the thermal expansion coefficient smaller than that of the wiring metal board for the metal board in the heat radiating side. Here, the reason why the copper system material is used for the metal board in the heat radiating side is that the copper element plastically deforms during the cooling process of the bonding process and such deformation will provide the effect to reduce a residual stress applied to the ceramics board in the bonding process.

Moreover, since the number of bonding areas is reduced, long-term reliability can be attained easily and the manufacturing process can also be simplified. Therefore, remarkable cost reduction may also be realized. As the ceramics board mounted on a circuit board, it is also possible to apply aluminum nitride and alumina, in addition to silicon nitride. A plurality of ceramics board may also be mounted as required. In this case, it is also possible to combine as required the silicon nitride board, aluminum nitride board and alumina board. However, when it is requested to further lower a thermal resistance using a thick circuit wiring board made of copper, alumina board or aluminum nitride board is insufficient in the strength and the silicon nitride board is most preferable.

### BRIEF DESCRIPTION OF THE DRAWINGS

FIGS. 1A and 1B are plan view and schematic cross-sectional view indicating a basic structure of a semiconductor device on the basis of the preferred embodiment of the present invention;

FIG. 2 is a schematic cross-sectional view of a composite member for a semiconductor device based on the embodiment of the present invention;

FIGS. 3A to 3D are graphs indicating dependence on thickness of a wiring metal board of thermal resistance, stress, and reliability of the semiconductor device based on the embodiment of the present invention;

FIGS. 4A and 4B are graphs indicating dependence on thickness of a silicon nitride board of crack breakdown rate and thermal resistance increasing rate based on the embodiment of the present invention;

FIG. 5 is a graph indicating transition of thermal resistance by a temperature cycle test of the semiconductor device based on the embodiment of the present invention;

FIG. 6 is a perspective view illustrating the essential portion of the semiconductor device based on a second embodiment of the present invention;

FIGS. 7A and 7B are plan view and cross-sectional view for describing details of the silicon nitride board on which a wiring layer is provided in the preferred embodiment of the present invention;

FIG. 8 is a diagram illustrating an example of the circuit structure of an insulated semiconductor device of the present invention;

FIG. 9 is a diagram illustrating a circuit of an inverter apparatus to which the semiconductor device of FIG. 8 is comprised;

FIG. 10 is a diagram for describing the operation when a supporting member having the thermal expansion coefficient in the longitudinal direction is 8 ppm/° C. and that in the short direction is 12 ppm/° C.;

FIGS. 11A and 11C are plan view and FIG. 11B is a cross-sectional view for describing details of a composite member in the preferred embodiment of the present invention;

FIGS. 12A and 12B are schematic diagrams of the insulated semiconductor device based on the sixth embodiment of the present invention in which the insulated board of the present invention is used;

FIGS. 12C and 12D are schematic diagrams of the insulated semiconductor device formed using the ordinary insulated board respectively corresponding to FIG. 12A and FIG. 12B;

FIGS. 13A to 13D are diagrams illustrating the manufacturing processes of the insulated board based on the first embodiment to the fourth embodiment of the present invention; and

FIGS. 14A to 14D are diagrams illustrating the manufacturing processes of the insulated board based on the fifth embodiment of the present invention.

### DETAILED DESCRIPTION OF THE PREFERRED EMBODIMENTS

A semiconductor device as an embodiment of the present invention will be described below. First, the semiconductor device as a first embodiment of the present invention will be described with reference to the accompanying drawings.

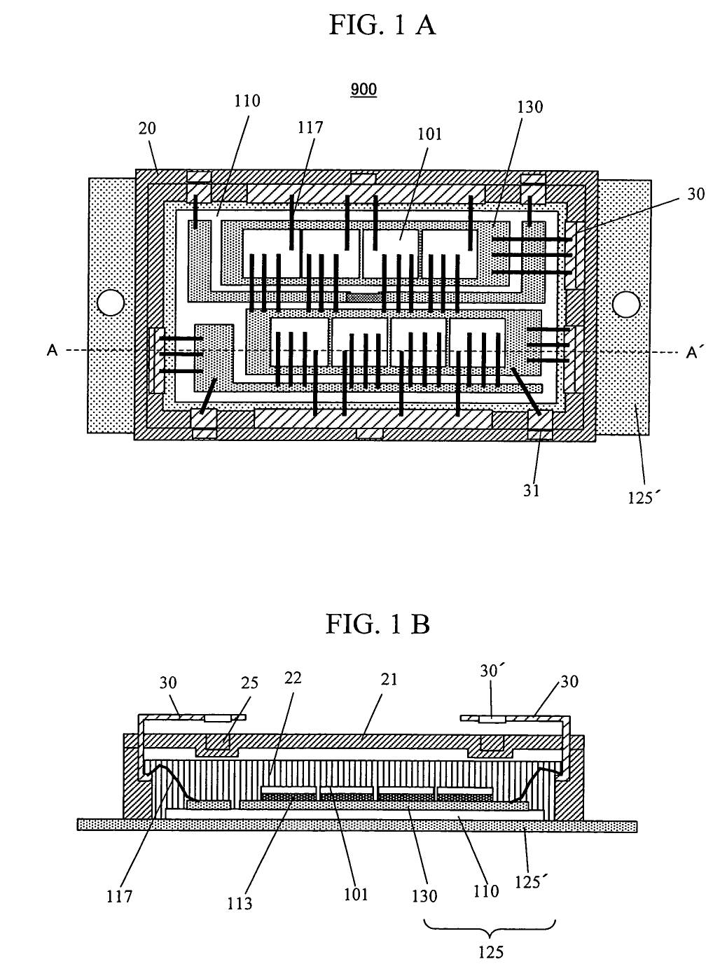

FIG. 1A and FIG. 1B illustrate examples of a basic structure of a semiconductor device as an embodiment of the present invention. FIG. 1A is a plan view of the semiconductor device, while FIG. 1B is a cross-sectional view along the line A-A′ in FIG. 1A. As illustrated in FIG. 1A and FIG. 1B, a semiconductor device 900 in this embodiment has a structure that a MOSFET element base material 101 is mounted as a semiconductor base material on a silicon nitride board 110 as a ceramics insulating board and a copper wiring board 130 provided on the silicon nitride board 110. Moreover, a polyphenyl sulphide resin case 20 provided with a main terminal 30 and an auxiliary terminal 31 is mounted to an insulated board (circuit board) 125.

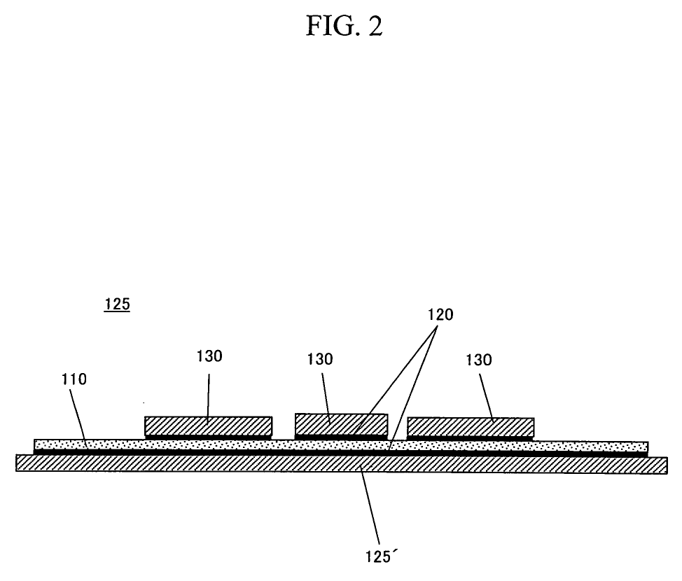

In this embodiment, the insulated board 125 is formed of a bonding structure in which a heat radiating wiring board 125′ formed of a composite metal plate wherein oxide copper powder particles are dispersed into a copper matrix and a silicon nitride board 110 are bonded with a silver system bonding metal layer 120 (illustrated in FIG. 2) and a copper circuit wiring board (rear surface metal board, hereinafter referred to as “copper wiring board”) 130 provided in the opposite surface of the silicon nitride board 110.

A wire bonding by Al fine lead 117 is implemented between the semiconductor base material 101 and the copper wiring board 130, between the semiconductor base material 101 and the auxiliary terminal 31, and between the copper wiring board 130 and the main terminal 30. The resin case 20 is filled with silicone gel resin 22 and a cover made of the polyvinyl sulphide resin is provided at the upper part of the resin case 20. On the copper wiring board 130 provided to the silicon nitride board 110, eight element base materials 101 are deposited in this example with the solder 113. As the solder 113, a paste solder material including flux is used.

Moreover, to the copper wiring board 130, a thermistor element for temperature detection (not illustrated) is brazed. This copper wiring board 130 is connected to the auxiliary terminal 31 with the Al fine lead 117. Although illustrated in FIGS. 1A and 1B, the case 20 is fixed to the insulated board 125 and also to the cover 21 with a silicone bonding resin. A thick area of the cover 21 is provided with a concave area 25, while the main terminal 30 with a hole 30′, respectively to store a screw for connecting the semiconductor device 200 to an external circuit wiring. The main terminal 30 and auxiliary terminal 31 are formed with Ni plating to a copper board punched into the predetermined shape and these are mounted with the injection molding method to the polyphenyl sulphide resin case 20.

FIG. 2 is a schematic cross-sectional view of a composite member used in the semiconductor device of this embodiment. The insulated board 125 is composed of a heat radiating wiring board 125′ formed of a composite metal board in which Cu₂O powder particles are dispersed into a matrix metal (Cu) (additional amount of Cu₂O: 20 vol %; thermal expansion coefficient: 10.0 ppm/° C.; thermal conductivity: 280 W/m•K; thickness: 1 mm; size: 42.4×85 mm), a silicon nitride board 110 (thermal expansion coefficient: 3.4 ppm/° C.; thermal conductivity: 90 W/m•K; thickness: 0.3 mm; size: 30×50 mm) which is fixed to one main surface of the heating radiating board 125′ with the Ag-system bonding metal layer 120, and a wiring metal board 130 formed of Cu or Cu alloy which is fixed to the other main surface of the ceramics insulated board 110 (silicon nitride board, hereinafter referred to as “ceramics board”). For example, thickness of the bonding metal layer 120 is adjusted to 50 μm and thickness of the wiring metal board 130 to 0.4 mm.

Regarding the wiring metal board 130 and heat radiating wiring board 125′ in the insulated board 135, following characteristics are required. Namely, (a) thermal conductivity is high, (b) bonding property with the ceramics board 110 is excellent, and (c) the plating layer of Ni, Sn, Ag, Au, Pt, Pd, and Zn or the like may be easily formed with a wet method. The characteristic (a) is significant for effective release for flow of heat from the semiconductor device to the external side via the matrix region.

To the board integrating the wiring board and heat radiating board described above, an Ni plating layer (thickness: 6 μm, not illustrated) is formed with the non-electrolyte wet plating process to the surface metal layers of the wiring metal board 130 and heat radiating wiring board 125′. The reason why the Ni plating layer is provided to the wiring metal board 130 (131, 132) is to acquire solder bondability and to enhance the wire bondability of the wiring metal board 130. Moreover, the Ni plating layer prevents internal denaturation by shutting off the device from the external atmosphere.

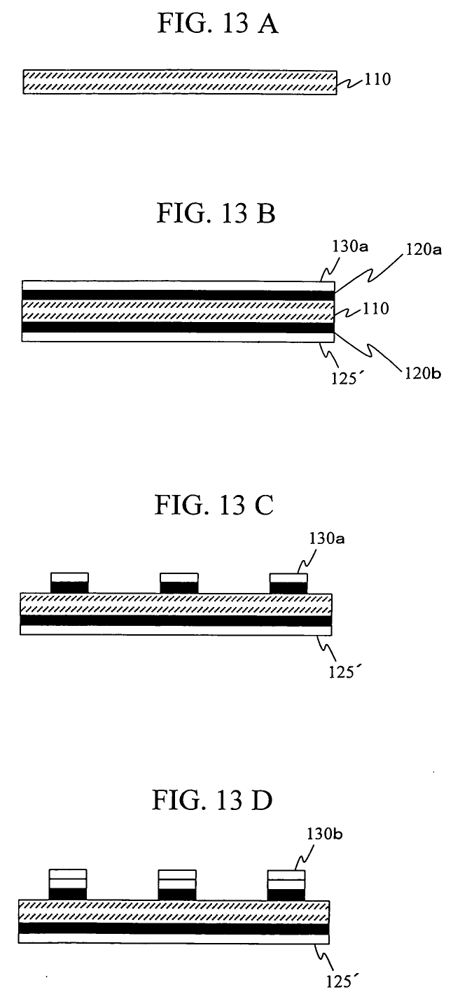

Next, the manufacturing process of the insulated board 125 will be described with reference to FIGS. 13A to 13D. First, the metal boards (Cu boards) for wiring and backing are respectively laminated to both surfaces of the ceramic board 110 after printing an Ag—Cu—Ti system brazing material paste and the laminated body is subjected to the heat treatment for the brazing of the metal board 130a, heat radiating wiring board 125′ and the ceramics board 110 (braze is indicated by the reference numerals 120a, 120b) (FIG. 13C). Thereafter, the selective etching is conducted to form a wiring layer 130a. If necessary, the selective etching is also conducted to the heat radiating wiring board 125′ for backing. Accordingly, the solder bondability and wire bondability are given to the wiring layer 130a. Moreover, non-electrolyte Ni plating is also implemented to give the solder bondability to the heat radiating wiring board 125′ for backing. Thereafter, a semiconductor chip 130b is allocated on the wiring layer 130a (FIG. 13d). Before and after the selective etching, several processes such as coating of mask agent, patterning, and removal of mask agent are included.

The subsequent semiconductor device manufacturing process can be simplified by producing the insulated board 125 with the processes described above. That is, in this insulated board 125, the composite metal board 131b which also works as a supporting member and the ceramics board 110 which also works as the insulated board are integrated with a bonding metal layer 120 and a wiring metal board 130 is formed on the semiconductor base material mounting surface of the ceramics board 110. Therefore, in the stage of manufacturing the semiconductor device 900, it is only required to mount the semiconductor base material 101 as another principal member with the soldering process (formation of the #1 solder layer).

Accordingly, the number of steps and components used may be reduced from that in the conventional method in the stage of assembling the semiconductor device 900, making contribution to reduction in manufacturing cost of the semiconductor device 900. In order to complete a semiconductor device, the wire bonding process, resin case fitting process and resin molding process are required but these processes may be introduced as the common process to the existing process.

The semiconductor device 900 of this embodiment cannot be attained only with integration of the wiring/supporting member and the ceramics board 110. In addition, it is required for this purpose to satisfy the requirement in the structure of the insulated board 125 described below. The optimum structure of the semiconductor device 900 will be described. One of the important requirements in the semiconductor device 900 based on this embodiment is that thickness of the wiring metal board 130 is adjusted to 0.1 to 1.0 mm as in the case of the ceramics board (thickness: 0.1 to 0.9 mm) and thickness of the bonding metal layer 120 is adjusted to 25 μm or more. As the upper limit, the preferable thickness is about 100 μm. The wiring metal board 130 also plays a role of the principal conductive path of the semiconductor device 900. If the predetermined current is fed, when the wiring metal board itself generates heat, heat generated by the wiring is superimposed to the heat of the semiconductor base material itself, narrowing the current region enabling safe operation in the semiconductor device. Therefore, in view of attaining a wider safe operation region, the wiring metal board 130 must be formed as thick as possible in order to reduce resistance. However, thickness of the wiring metal board 130 is restricted by the following factors.

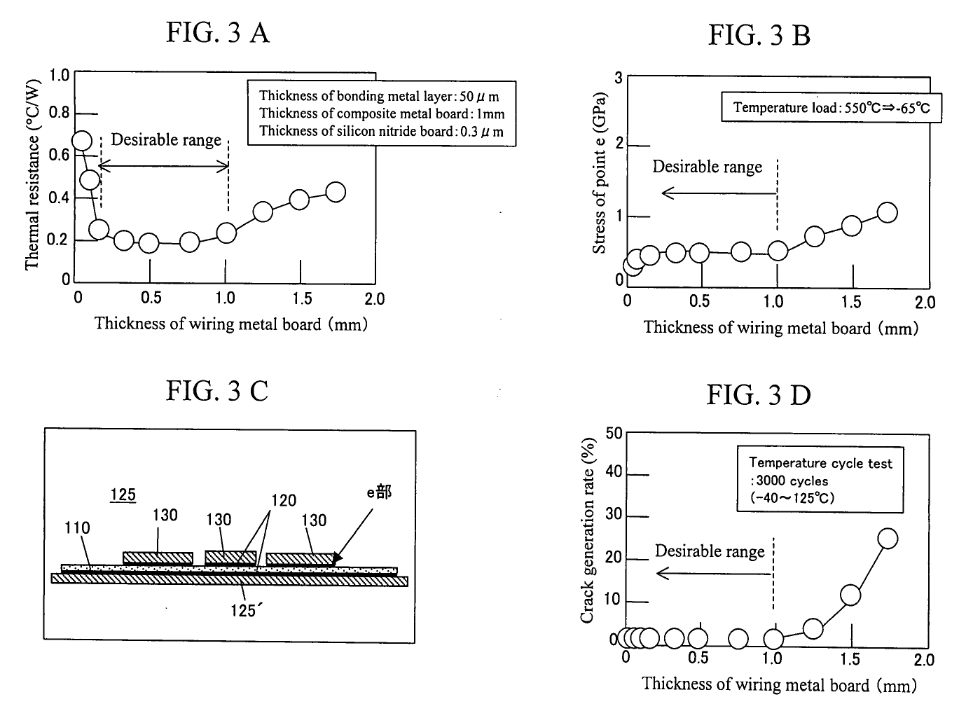

FIGS. 3A to 3D are graphs indicating thermal resistance, stress, and reliability of semiconductor device depending on thickness of the wiring metal board. FIG. 3A is a graph indicating relationship between thickness of the wiring metal board and thermal resistance. Thermal resistances indicated in FIG. 3A are value thereof when the four semiconductor base materials 101 are operating in the semiconductor device 900 illustrated in FIG. 1. In the thinner region of the wiring metal board 130, thermal resistance becomes high because heat generated in the semiconductor base material 101 is not diffused easily in the lateral direction. As the thickness of wiring metal board 130 increases, influence of heat diffusing in the lateral direction increases and thereby thermal resistance is gradually lowered. When the wiring metal board 130 becomes further thick, thermal resistance is increased again because influence of vertical direction element in thermal resistance of the wiring metal board 130 itself becomes distinctive. Here, the semiconductor device 900 has a current capacity of 400 A and its target thermal resistance is set to 0.4° C./W or less in order to realize electrically stable operation. Thickness of the wiring metal board 130 satisfying this target thermal resistance is within the range of 0.1 to 1.0 mm.

Next, thermal stress of FIG. 3B will then be described. The vertical axis of FIG. 3B indicates a stress of the silicon nitride board obtained through the simulation (temperature load: 550° C. to 65° C.) and it is the value at the point e (part corresponding to the end part of the wiring metal board, the part indicating the highest stress in the insulated board 125) in the schematic cross-sectional view of FIG. 3C. Here, it can be understood that stress at the point e increases as the wiring metal board 130 becomes thick. An ordinary breakdown stress of the silicon nitride board is about 700 MPa and the stress at the point e is required not to exceed this value. When this point is considered, selected thickness of the wiring metal board 130 is 1.0 mm or less. If the stress at the point e becomes excessively high, through-crack which will be described later is generated, in addition, crack is also generated extending to the silicon nitride board region just under the wiring metal board 130 from the starting point e, and thereby thermal resistance increases.

Next, attention is paid to the crack generation rate of FIG. 3D. Crack in FIG. 3D suggests a mechanical breakdown of the silicon nitride board 110 generated after implementation of the temperature cycle test (3000 cycles, −40 to 125° C.) of the semiconductor device 900 (crack generated through the side of bonding metal layer 120 from the starting point e). As illustrated in FIG. 3D, the crack breakdown cannot be observed until the thickness reaches 1.0 mm but when the thickness exceeds 1.0 mm, the crack generation rate tends to increase as the wiring metal board 130 becomes thick. Here, the crack observed starts from the area corresponding to the point e. The silicon nitride board 110 is provided to maintain insulation property of the semiconductor device 900. If this silicon nitride board 110 breaks, safe operation of the semiconductor device 900 is impeded. The wiring metal board 130 selected from this point of view has the thickness of 1.0 mm or less.

It can be understood by integrating the evaluation results of thermal resistance, stress, and reliability described above that thickness of the wiring metal board 130 satisfying all requirements of thermal resistance, stress, and reliability is in the range of 0.1 to 1.0 mm. FIGS. 3A to 3D indicate the results when thickness of head radiating wiring board 125′ formed of a composite metal board is 1 mm, thickness of the bonding metal layer 120 is 50 μm, and thickness of silicon nitride board 110 is 0.3 mm. However, the similar results have been obtained when the heat radiating wiring board 125′ is in the range of 1 to 3 mm, bonding metal layer 120 in the range of 0.025 to 0.5 mm, and silicon nitride board 110 in the range of 0.2 to 0.9 mm.

(Thickness of Silicon Nitride Board)

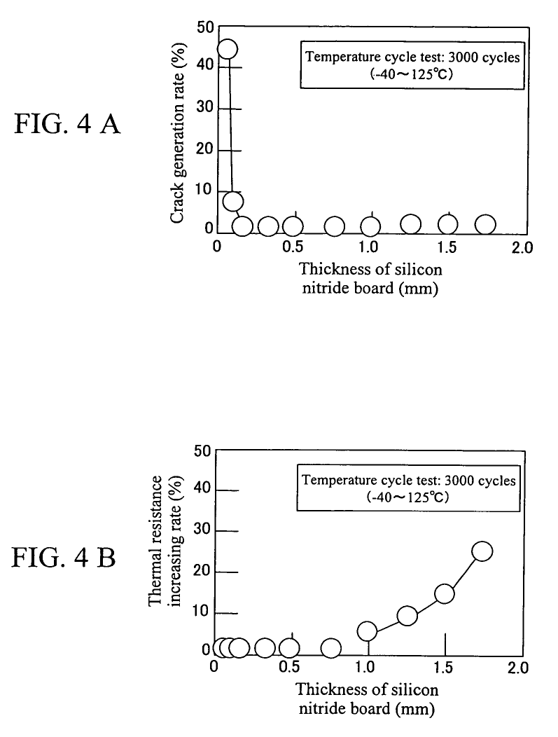

The silicon nitride board 110 also forms the principal heat flowing path in the semiconductor device 900. In order to attain excellent heating radiating property by suppressing thermal resistance, it is preferable that this member having lower thermal conductivity among the heat flowing paths is formed as thinner as possible. However, since this board is insulated material, the performance thereof must also be considered. FIGS. 4A and 4B are diagrams indicating dependence on the thickness of silicon nitride board of the crack breakdown rate and thermal resistance increasing rate. The crack breakdown rate of FIG. 4A will be described. Here, crack breakdown means a mechanical breakdown of the silicon nitride board 110 by the temperature cycle test (3000 cycles, −40 to 125° C.). As illustrated in FIG. 4A, the crack breakdown of the silicon nitride board 110 is never generated in the area having the thickness of 0.2 mm or more. Meanwhile, in the area having the thickness of 0.2 or less, the crack breakdown is generated. In this case, breakdown means the crack generated through the side of the bonding metal layer 120 starting from the point e described above. From the view point of safe operation of the semiconductor device 900, it is preferable to select the thickness of the silicon nitride board 110 to the range of 0.2 mm or more.

Next, the thermal resistance increasing rate of FIG. 4B will be described. If fatigue breakdown of the bonding metal layer 120 progresses when the temperature cycle test goes on (3000 cycles, −40 to 125° C.), the heat radiating path is shut down. Increase in the thermal resistance results from such shut-down of the heating flowing path. In the region where thickness is 0.9 mm or less, thermal resistance is never varied but in the region thicker than above thinner region, thermal resistance increases. For safe operation of the semiconductor device 900, it is preferable to select thickness of the silicon nitride board 110 to the range of 0.9 mm or less.

From overall integration of the evaluation results of the crack breakdown rate and thermal resistance increasing rate described above, the thickness of the silicon nitride board 110 which satisfies all requirements described above is in then range of 0.2 to 0.9 mm. FIGS. 4A and 4B indicate the results when thickness of heat radiating wiring board 125′ formed of a composite metal board is 3 mm, thickness of wiring metal board 130 is 0.4 mm, and thickness of bonding metal layer 120 is 50 μm. The similar results have also been obtained when the heat radiating wiring board 125′ is in the range of 1 to 3 mm, the wiring metal board 130 in the range of 0.1 to 1.0 mm, and the bonding metal layer 120 in the range of 0.025 to 0.5 mm.

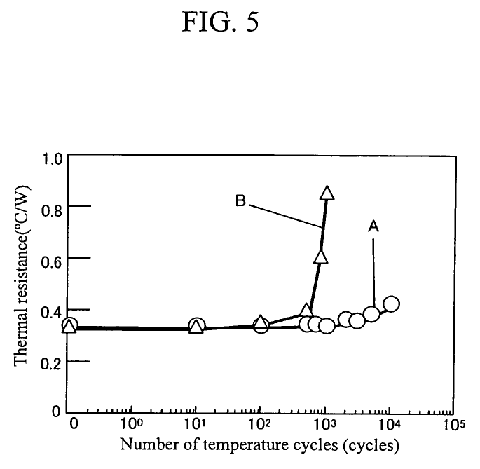

FIG. 5 is a graph indicating transition of thermal resistance when the temperature cycle test is conducted to the semiconductor device of the embodiment of the present invention. The semiconductor device 900 is formed by mounting a MOSFET element base material 101 on the insulated board 125 formed of the heat radiating wiring board 125′ in the thickness of 1 mm (20 vol % Cu₂O), silicon nitride board 110 in the thickness of 0.3 mm, wiring metal board 130 in the thickness of 0.6 mm, and bonding metal layer 120 in the thickness of 50 μm. It can be understood that the semiconductor device 900 (curve A) in this embodiment can maintain the thermal resistance value similar to the initial value (0.35° C./W) even after the temperature cycles of 10000 cycles.

Meanwhile, in the case of semiconductor device (curve B) for comparison, thermal resistance starts to increase in the temperature cycle of 1000 cycles. The semiconductor device for comparison is respectively adjusted to the thickness of 3 mm in the composite metal board, 15 μm in the bonding metal layer, 0.2 mm in the silicon nitride board, and 1.5 mm in the wiring metal board. Here, when the operation life for heat radiating property is defined as the “number of temperature cycles when the thermal resistance reaches 1.5 times the initial thermal resistance”, the life of sample for comparison is about 2000 cycles and the life of the sample 900 in the embodiment of the present invention is 10000 cycles or more. The reason why the sample for comparison reaches quickly the operation life is that the silicon nitride board just under the wiring metal board generates the crack breakdown due to a stress at the point e and that principal heat radiating path is shut-down because of the fatigue breakdown of the bonding metal layer. In the sample for comparison, since thickness of the composite metal board, silicon nitride board, bonding metal board and wiring metal board is not adjusted adequately, balance of stress and strain is rather bad in the entire part of the insulated board 125.

In the semiconductor device 900 in this embodiment, the Ni plating layer (thickness: 6 μm) is provided at the surface of the heat radiating wiring board 125′ formed of the wiring metal board 130 and composite metal board. The Ni plating layer of the wiring metal board 130 may be replaced with a metal material such as Sn, Ag, Au, Pt, Pd, Zn, and Cu or the like which assures solder bondability and wire bondability. Moreover, thickness may also be selected to the desired value within the range for preventing deterioration in quality of the heat radiating wiring board 125′ by acquiring the solder bondability and wire bondability. The Ni plating layer on the heat radiating wiring board 125′ has a role of maintaining quality of internal side and surface of the heat radiating wiring board 125′ but Ni may also be replaced with various metal materials. On the contrary, the plating may also be eliminated if it is unnecessary for maintaining the quality. Moreover, the Ni plating layer described above may also be replaced with the a layer formed by laminating a plurality of metal materials selected from the group of Ni, Sn, Ag, Au, Pt, Pd, Zn, and Cu.

The ceramics board 110 mounted on the insulated board 125 may also be formed, in place of the silicon nitride, of aluminum nitride (AlN, thermal conductivity: 190 W/m•K; thermal expansion coefficient: 4.3 ppm/° C.) and alumina (Al203, thermal conductivity: 20 W/m•K; thermal expansion coefficient: 7.2 ppm/° C.). In this case, when these ceramics board 110 are formed in the thickness in the range of 0.25 to 1.0 mm, the effect similar to that when the silicon nitride board is applied can be attained by combining the heat radiating wiring board 125′ in the thickness of 1 to 10 mm, wiring metal board 130 of 0.1 to 1.2 mm, and the bonding metal layer 120 of 25 μm or more. Moreover, the ceramics board may be mounted in the plural numbers as required. In this case, the silicon nitride board, aluminum nitride board and alumina board may be combined. However, when it is requested to lower the thermal resistance value by using a thick copper circuit wiring board in the thickness of about 0.5 mm, crack is generated in the board itself due to insufficient strength of the alumina board or aluminum nitride board. Accordingly, use of such alumina board and aluminum nitride board is not practical. In this point, it is preferable to use a highly strength silicon nitride board.

The semiconductor device 900, to which the insulated board 125 described above, is effective to provide a highly reliable and low cost device in which thermal stress or strain which is generated in the manufacturing process or during the operation thereof may be alleviated and each member is freed from deformation, denaturation, and breakdown.

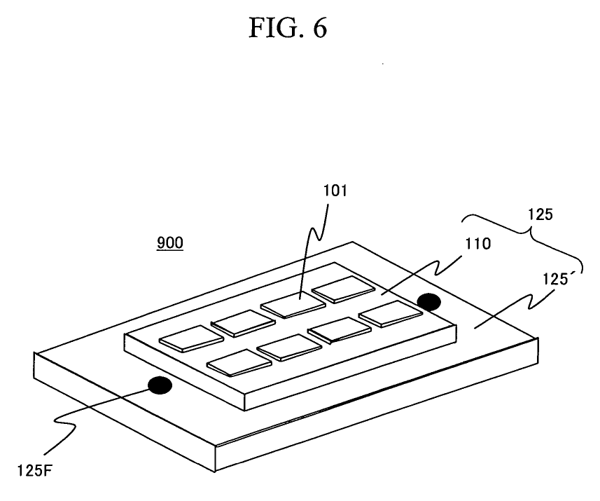

Next, the second embodiment of the present invention will be described with reference to the accompanying drawings. FIG. 6 is a schematic perspective view illustrating the essential portion of the semiconductor device on the basis of this second embodiment. As illustrated in FIG. 6, the semiconductor board 900 of the second embodiment has a structure that a semiconductor base material 101 is mounted through the soldering process on an insulated board 125 formed by integration of a silicon nitride board as the ceramics board 110 (30×50×0.3 mm) and a heat radiating wiring board 125′ as the supporting member formed of copper. In this case, an Ni plating layer (thickness: 6 μm, not illustrated), for example, is provided in the exposed area of the heat radiating wiring board 125′ as the supporting member. The heat radiating wiring board 125′ as the supporting member has a size, for example, of 42.4 mm×85 mm×3 mm and is provided with a mounting hole (for example, diameter: 5.6 mm) 125F at the circumference area thereof.

The heat radiating wiring board 125′ as the supporting member and the silicon nitride board 110 are integrated with a bonding metal layer 120 (thickness: 50 μm, refer to FIG. 2) formed of Ag-system brazing material and the eight MOSFET element base materials (7×7×0.28 mm) 101 as the semiconductor base material 101 are mounted on the wiring metal board 130 (thickness: 0.4 mm, refer to FIG. 2) formed of copper provided on the silicon nitride board 110.

The element base material 101 and the wiring metal board 130 are bonded with the Sn—3Ag—0.5Cu solder material 113 (thickness: 100 μm, refer to FIG. 1). The heat radiating wiring board 125′ as the supporting member is processed with the sand-blast method, for example, and is controlled in the thermal expansion coefficient. In this embodiment, the material of the heat radiating wiring board (supporting member) is characterized in use of copper (Cu) as the material in the similar system as the wiring metal board 130. Moreover, the thermal expansion coefficient of the heat radiating wiring board 125′ is 12 ppm/° C. the processes are executed to make smaller the thermal expansion coefficient than that of copper (Cu). As described above, the material which is similar to that of the wiring metal board 130 can be used as the supporting member by adequately controlling the thermal expansion coefficient through the mechanical process.

In this embodiment, copper (Cu) is used for both wiring metal board and supporting member. However, it is also possible to use, for example, a Cu alloy of the same composition as the wiring metal board which is controlled in the thermal expansion coefficient by using the Cu alloy for the wiring metal board 130 and conducting the process such as the mechanical process such as the sand-blast method to the heat radiating wiring board 125′ as the supporting member. In this embodiment, since the wiring metal board 130 and supporting member (heat radiating wiring board) 125′ may be formed of the material of the same system, it is not required to change the material of the bonding material for bonding with the ceramics board 110, the wiring metal board 130 and heat radiating wiring board (supporting member) 125′ can be bonded with the ceramics board 110 by the simultaneous process resulting in the excellent process characteristic without any complicated process. The semiconductor device based on this embodiment has been built into an inverter apparatus for electrical vehicle.

In the structure similar to that of this embodiment illustrated in FIG. 6, it is also possible to use a material in which the Cu₂O powder particles are dispersed (amount of addition: 20 vol %) in addition to the matrix metal (Cu) as the principal material of the supporting member (heat radiating wiring board) as the supporting member (heat radiating wiring board, thermal expansion coefficient: 10.0 ppm/° C.; thermal conductivity: 300 W/m•K) 125′ by processing the supporting member with the sand-blast method or by omitting such process. Moreover, the insulated board 125 having the cross-sectional structure illustrated in FIG. 2 which consumes the maximum electrical power of 400 W is adapted to the semiconductor device 900 of FIG. 6.

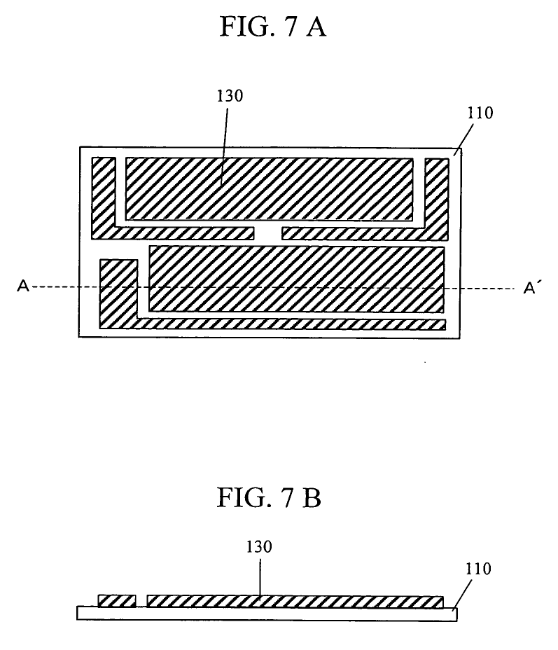

FIGS. 7A and 7B are a plan view (FIG. 7A) and a cross-sectional view (FIG. 7B) of the detail structure of the silicon nitride board 100 on which the wiring is provided. The silicon nitride board 110 illustrated in FIGS. 7A and 7B is a sintered body in size of 30 mm×50 mm×0.3 mm (thermal expansion coefficient: 3.4 ppm/° C.; thermal conductivity: 90 W/m•K) and the wiring metal board 130 in the thickness of 0.4 mm is provided to the principal surface (upper surface of FIG. 7A) which is not bonded with the heat radiating wiring board 125′ (not illustrated) formed of a composite metal board. This wiring metal board 130 is formed of copper or a copper alloy. The opposite surface of the silicon nitride board 110 is bonded with the heat radiating wiring board 125′ formed of a composite metal board via the metal bonding layer 120 using the Ag-system brazing material. The semiconductor device 900 is combined with the other members. Structure of the semiconductor device 900 will be described in more detail with reference to FIGS. 1A and 1B. The MOSFET element base materials 101 are mounted as the semiconductor base materials on a copper wiring board 130 provided on the silicon nitride board 110.

The polyphenyl sulphide resin case 20 provided with the main terminal 30 and auxiliary terminal 31 is mounted to the insulated board 125. The insulated board 125 is formed of a composite material in which the heat radiating wiring board 125′ formed by dispersing the Cu₂O powder particles into the copper matrix and the silicon nitride board 110 are bonded with a bonding metal layer 120 formed of the Ag brazing material and the wiring metal board 130 formed of copper or copper alloy is provided to the opposite surface of the silicon nitride board 110. The wire bonding of the Al fine lead 117 is implemented between the semiconductor base material 101 and wiring metal board 130, between the semiconductor base material 101 and the auxiliary terminal 31, and between the wiring metal board 130 and the main terminal 30. The inside of case 20 is filled with the silicone gel resin 22 and the polyphenyl sulphide resin cover 21 is provided at the upper part of the case 20. Here, the eight MOSFET element base materials 101 are deposited with the Sn—3Ag—0.5Cu solder 113 on the copper wiring board 130 provided to the silicon nitride board 110. Deposition by the Sn—3Ag—0.5Cu solder 113 is performed under the lowerly evacuated atmosphere using the paste solder including flux. Moreover, the thermistor element 34 for temperature detection is deposited among the wiring metal boards 130c with the Sn—3Ag—0.5Cu solder 124 (not illustrated) and the wiring metal board 130c is connected to the auxiliary terminal 31 through the Al fine lead 117.

As illustrated in FIG. 1, the areas between the case 20 and insulated board 125 and between the case 20 and cover 21 are filled with the fixed silicone bonding resin 35 (not illustrated). At the thick area of the cover 21, a concave area 25 is provided, while a hole 30′ at the main terminal 30 in view of storing a screw (not illustrated) for connecting the semiconductor device 900 to an external circuit. The main terminal 30 and auxiliary terminal 31 are formed of the Ni-plated copper plate punched previously to the predetermined shape. These terminals are mounted to the polyphenyl sulphide resin case 20 with the ejection molding method. The semiconductor device 900 in the structure described above has the external size of 45 mm×87 mm×15 mm. Amount of curvature of the insulated board 125 of the semiconductor device 900 is as small as 50 μm.

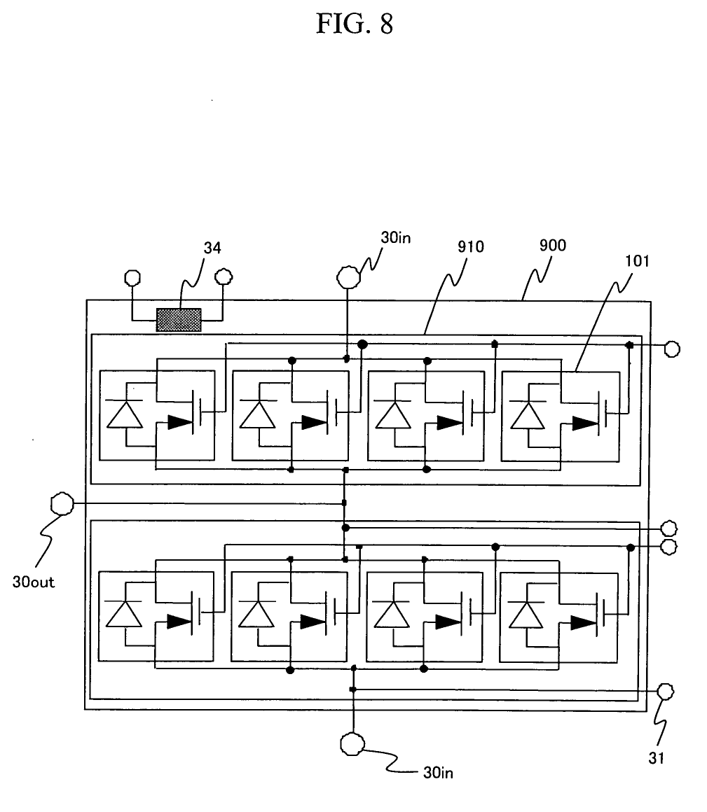

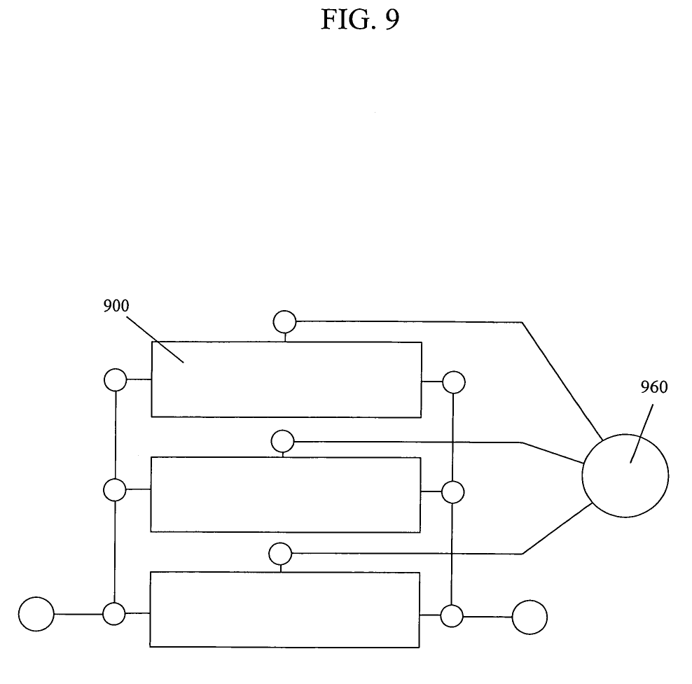

FIG. 8 is a diagram illustrating an example of the structure of a circuit of the semiconductor device 900. Blocks 910 for two systems allocating in parallel the MOSFET elements (four elements) 101 are provided, each block 910 is connected in series, and an input main terminal 30in, an output main terminal 30out and an auxiliary terminal 31 are led from the predetermined area to form the essential portion of the semiconductor device 900. Moreover, the thermistor 34 for temperature detection to detect temperature during operation of this circuit is also allocated within the semiconductor device 900 independent of the MOSFET elements (four elements) 101. The semiconductor device 900 is finally built, for example, into an inverter apparatus for controlling the number of rotations of a motor 960 illustrated in FIG. 9. The inverter apparatus and motor can be assembled into an electrical vehicle as a power source thereof. In the electrical vehicle, since the drive mechanism up to the wheels from the power source can be simplified, mechanical shock generated when the velocity is changed can be alleviated, smoother running can be realized, and vibration and noise may also be reduced in comparison with the conventional vehicle in which the running speed has been changed through difference in the engagement ratio of gears.

Moreover, the inverter apparatus comprising the semiconductor device 900 may also be assembled into an air-conditioner. In this case, higher efficiency can also be attained in comparison with that attained by using the conventional AC motor. This merit is effective for reduction in the power consumption when the air-conditioner is used. Moreover, the time required until the room temperature reaches the preset temperature from the start of operation can be shortened than that required when the conventional AC motor is used.

The similar effect can also be achieved when the semiconductor device 900 is assembled, as in the case of this embodiment, into an apparatus for stirring or generating flow of the other fluid, for example, a washing apparatus and a fluid circulating apparatus or the like.

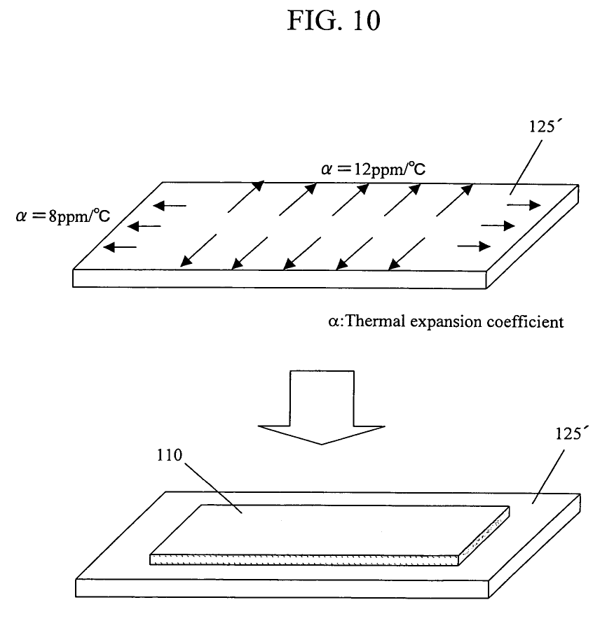

A semiconductor device based on the third embodiment of the present invention will be described with reference to the accompanying drawings. This third embodiment will be described with reference to FIG. 6 and FIG. 10. As illustrated in FIG. 6, the semiconductor base material 101 is mounted with the soldering process on the insulated board 125 integrating the silicon nitride board (30×50×0.3 mm) as the ceramics board 110 and the heat radiating wiring board 125′ as the supporting member. The Ni plating layer (thickness: 6 μm, not illustrated) is provided to the exposed area of the heat radiating wiring board 125′. The heat radiating wiring board 125′ has the size of 42.4 mm×85 mm×3 mm and a mounting hole (diameter: 5.6 mm) 125F is provided to the circumference thereof. The heat radiating wiring board 125′ and the silicon nitride board 110 are integrated with the bonding metal layer 120 (thickness: 50 μm, not illustrated) formed of the Ag-system brazing material. The eight MOSFET element base materials (7×7×0.28 mm) 101 are mounted, as the semiconductor base materials 101, on the wiring metal board 130 (thickness: 0.4 mm, not illustrated) formed of a copper alloy provided on the silicon nitride insulated board 110.

The element base material 101 and the wiring metal board 130 are bonded with the Sn—3AG—0.5Cu solder material 113 (thickness: 100 μm, not illustrated). The heat radiating wiring board (supporting member) is controlled in its thermal expansion coefficient with a degree of the rolling process. A Cu composite material including Cu₂O of 20 wt % is used as the material of the heat radiating wiring board (supporting member) as in the case of the first and second embodiments. However, as illustrated in FIG. 10, the thermal expansion coefficient in the longitudinal direction is 8 ppm/° C., while 12 ppm/° C. for the shorter direction. A total deformation may be suppressed by manufacturing a circuit board in which the direction having the smaller thermal expansion coefficient is matched with the longitudinal direction of the ceramics board. Since the directional property (anisotropy) is given to the thermal expansion coefficient as described above, a member including less amount of Cu₂O may also be used. Moreover, it is also possible for the composite material to give such anisotropy to the thermal expansion coefficient as described above, but it is also possible not only for the composite material but also for pure metal material (for example, pure copper). Accordingly, application of this embodiment of the present invention is capable of widening the selection range of the supporting member. The method for acquiring the anisotropy of thermal expansion coefficient implemented in this third embodiment will be below. The Cu material including Cu₂O is rolled up to the predetermined shape. In this case, organization of Cu and Cu₂O are rolled in the rolling direction. This rolling direction shows a larger thermal expansion coefficient, while the perpendicular direction to this rolling direction shows a smaller thermal expansion coefficient. Such anisotropy of thermal expansion coefficient may be controlled with the amount of Cu₂O included and a degree of rolling process. The wiring board in the heat radiating side based on this third embodiment may be used by obtaining the board material of the predetermined shape from the rolled material having anisotropy of thermal expansion coefficients.

The semiconductor device obtained as described above may also be assembled for actual operation into an inverter apparatus for electric vehicle.

Next, a fourth embodiment of the present invention will be described below with reference to the accompanying drawings. The semiconductor device of this fourth embodiment functions like the insulated semiconductor device of the other embodiments.

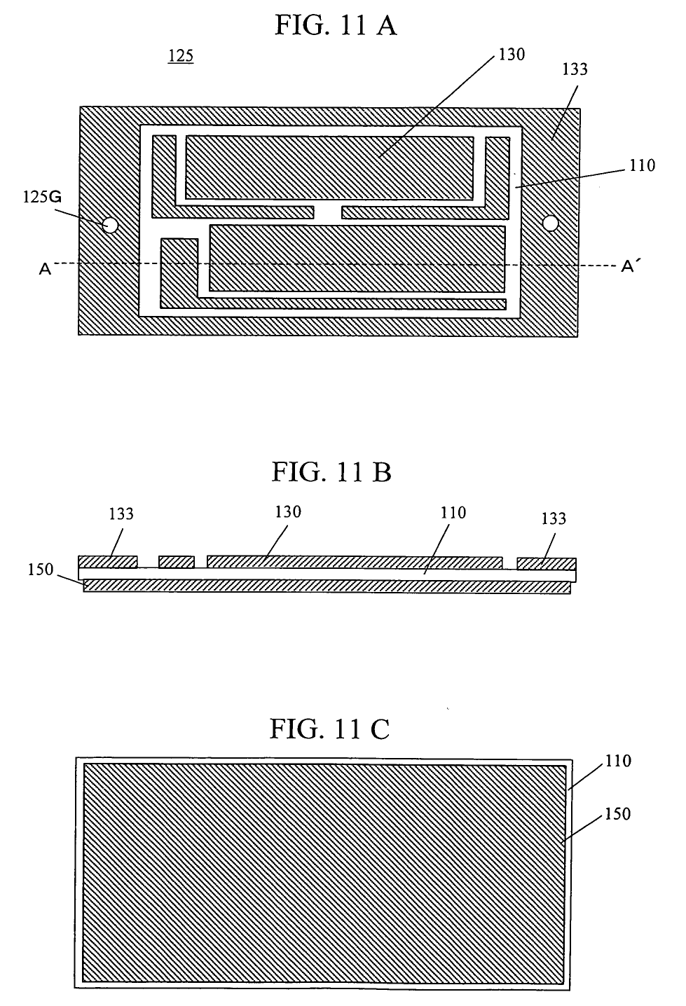

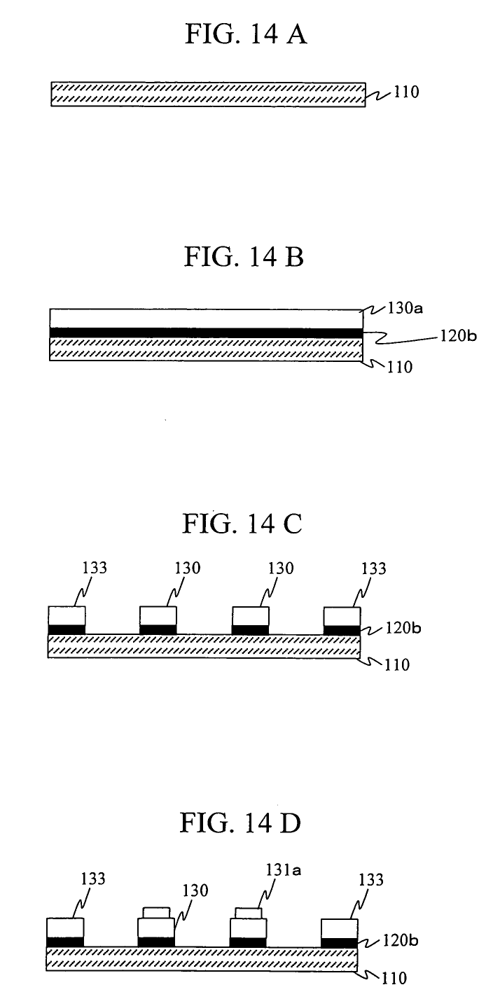

FIGS. 11A, 11B, and 11C are respectively a plan view of the front surface, a cross-sectional view and a plan view of the rear surface illustrating in detail an example of the structure of the composite metal board 125 used in the semiconductor device of this fourth embodiment. FIGS. 14A to 14D illustrate the principal manufacturing processes of the insulated semiconductor device of this embodiment. First, the manufacturing processes of the insulated board 125 will be described with reference to FIGS. 14A to 14D. A ceramics board is prepared first (FIG. 14A). After the Ag—Cu—Ti system brazing material paste is printed on the surface (front surface) of the ceramics board 110, a metal board (Cu board) for wiring is laminated on the front surface of the ceramics board 110, and the metal board 130a and ceramics board 110 are brazed (braze is designated as reference numeral 120b) through the heat treatment of the laminated body (FIG. 14B). Thereafter, the metal board 130a is etched preferably for simultaneously processing the wiring layer 130 and the peripheral metal board 133. The wiring layer 130 is given the solder bondability and wire bondability, and a semiconductor chip 131a is allocated. Before and after these processes, coating of mask agent, patterning, and removal of mask agent are included.

Next, a structure of the insulated board manufactured with the processes described above will then be described. As illustrated from FIG. 11A to FIG. 11C, the insulated board 125 based on this embodiment basically has the structure similar to that of the first embodiment and only difference will be described below. As is apparent from comparison with FIG. 7, the composite metal board 125 used in the semiconductor device of this embodiment has the structural characteristic that the metal wiring board 130 is formed on the silicon nitride board 110, a peripheral metal board 133 is also provided to the external circumference of the metal wiring board 130, and a rear surface metal board (metal wiring board) 150 is also provided to almost the entire part of the rear surface of the silicon nitride board 110.

The materials of the same kind should preferably be used for the peripheral metal board 133 and metal wiring board 130. Moreover, it is preferable that these boards are formed of copper or a copper alloy. The rear surface metal board (metal wiring board) 150 is similar in the material as the heat radiating wiring board (supporting board) 125′ which is used in the first embodiment to the third embodiment. Thickness of the peripheral metal board 133 may be different from that of the rear surface metal board (metal wiring board) 150, but the thickness of these boards is preferably almost identical. The rear surface metal board (metal wiring board) 150 and the silicon nitride board 110 have almost the equal area. The reference numeral 125G designates a hole for screwing.

With employment of the structure illustrated in FIG. 11A to FIG. 11C, the peeling resistance between the silicon nitride board 110 and peripheral metal board 133 and rear surface metal board (metal wiring board) 150 can be improved. When the temperature cycle test (−55 to 150° C., 6000 cycles, number of samples: 20) has been conducted to the insulated board 125 of this embodiment, peeling has never been observed in the peripheral metal board 133 and rear surface metal board (metal wiring board) 150.

The insulated semiconductor device 900 of the structure illustrated in FIG. 1 has been manufactured using the insulated board 125 of the structure described above. As a result, the performance of the insulated semiconductor device 900 has been verified to be identical to that of the semiconductor device of the first embodiment. Moreover, even when the temperature cycle test which is similar to that in the first embodiment is conducted up to 12000 cycles, thermal resistance of the insulated semiconductor device 900 has also been verified to sustain the value which is almost equal to the initial value. As described above, according to the insulated semiconductor device 900 of this embodiment, a semiconductor device having excellent reliability can be realized.

In addition, the tightening test similar to that in the first embodiment has also been conducted under the screw tightening torque of 50 Kg to the insulated semiconductor device 900 of this embodiment. Any mechanical damage of the insulated board 125 and deterioration in the electrical functions of the insulated semiconductor device 900 due to this tightening test cannot be recognized in the samples (10 samples) which have actually been subjected to the test. This result may be assumed to be based on the fact that the rear surface metal board (metal wiring board) 150 provided to the insulated board 125 functions as a reinforcing material of the silicon nitride board 110 and that the peripheral metal board 133 provided to the insulated board 125 also functions as the reinforcing material of the silicon nitride board 110. Since both materials have almost the equal thermal expansion coefficients, influence of heat at both surfaces of the insulated board 125 may be cancelled. Accordingly, it can be assumed that more excellent result is attained.

Moreover, when the falling test is implemented to the insulated semiconductor device 900, any mechanical damage of the insulated board 125 and deterioration in electrical functions of the insulated semiconductor device 900 cannot be recognized in the ten test samples because the rear surface metal board (metal wiring board) of the insulated board 125 functions as the reinforcing material of the silicon nitride board 110 and the peripheral metal board 133 of the insulated board 125 also functions as the reinforcing material of the silicon nitride board 110.

The insulated semiconductor device 900 of this embodiment can be assembled to various apparatuses as in the case of the first embodiment. In this case, excellent performance and reliability have been verified. Moreover, amount of curvature of the insulated board of the insulated semiconductor device 900 of this embodiment has been proved to show very excellent flatness of ±20 μm (the sign + is applied when the wiring metal board side is projected and the sign − is applied when the rear surface metal board side is projected). The reason of such excellent flatness is that curvature (+) due to the bimetal effect between the silicon nitride board 110 and the rear surface metal board (metal wiring board) 150 in the peripheral area of the insulated board 125 is compensated by the curvature (−) in the inverse direction due to the bimetal effect between the silicon nitride board 110 and the peripheral metal board 133. This point is particularly preferable for the insulated semiconductor device in which the board 125 is screwed. Moreover, thermal resistance in the completed semiconductor device can be lowered and long-term reliability can also be acquired. The rear surface metal board 150 may be formed of the materials (copper or copper alloy) similar to the materials of wiring metal board 130 and peripheral metal board 133.

Next, a fifth embodiment of the present invention will be described with reference to the accompanying drawings. The semiconductor device of this fifth embodiment is highly related to the semiconductor device of the fourth embodiment and therefore it will be described with reference to FIGS. 1A and 1B. As illustrated in FIGS. 11A and 11B, the semiconductor device of this embodiment has the structure that the insulated board 125 is formed by forming the metal wiring board 130 on the silicon nitride board 110. Moreover, the peripheral metal board 133 is preferably provided to the external circumference of the metal wiring board 130 in order to continuously surround the center area. However, the metal board is provided to the rear surface of the silicon nitride board 110. In this embodiment, the peripheral metal board 133 is formed preferably with the material similar to the metal wiring board 130. Moreover, such board is preferably formed of copper or copper alloy.

If the metal board is not provided to the rear surface, excellent reliability can be obtained like the semiconductor device based on the fourth embodiment and the structure can also be simplified with employment of the structure of FIGS. 11A to 11C.

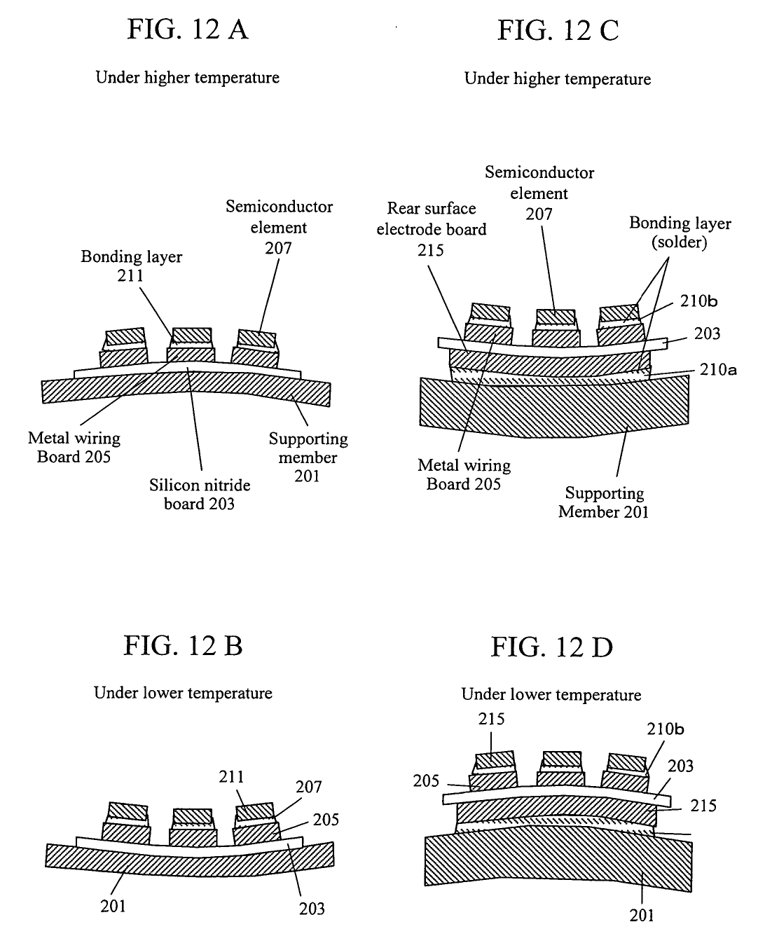

Next, a sixth embodiment of the present invention will be described with reference to the accompanying drawings. This embodiment may be adapted in common to all embodiments described above. FIGS. 12A and 12B schematically illustrate the insulated semiconductor device manufactured using the insulated board of this embodiment, while FIGS. 12C and 12D are schematically illustrate the insulated semiconductor device using an ordinary insulated board. FIGS. 12A and 12B are corresponding to each other. This embodiment will be described through comparison of these devices with reference to FIG. 12A to 12D.

As illustrated in FIGS. 12A and 12B, the semiconductor device of this embodiment comprises the metal wiring board 205 provided at the front surface side of the silicon nitride board 203 and the semiconductor element (chip) 207 which is bonded with the metal wiring board 205 via the bonding layer 211 and also comprises, at the rear surface side, the supporting member (heat radiating wiring board) 201 (except for the fifth embodiment). On the other hand, the ordinary semiconductor device comprises the metal wiring board 205 provided at the front surface side of the silicon nitride board 203 and the semiconductor element (chip) 207 bonded with the metal wiring board 205 via the bonding layer 215 and also comprises, in the rear surface side, the rear surface electrode board 215 and the supporting member 201 which is bonded with the rear surface electrode board 215 via the bonding layer (solder) 210a.

In the ordinary semiconductor device, the device is curved projecting to the lower side under the higher temperature (FIG. 12C) and also curved projecting to the upper side under the lower temperature (FIG. 12D). Accordingly, the heat conductive grease is easily extruded to the outside sometimes resulting in rise of thermal resistance.

Meanwhile, the semiconductor device of the embodiments described above is curved projecting to the upper side under the higher temperature (FIG. 12A) and is also curved projecting to the lower side under the lower temperature (FIG. 12B). Amount of projection, namely amount of curvature is about several tens of micrometers. This amount of curvature is enough to suppress extrusion of heat conductive grease to be coated between the supporting board of semiconductor device and a power converting apparatus when the semiconductor device is installed into the power converting apparatus. As described above, the semiconductor device of this embodiment has a merit to prevent extrusion of the grease.

For the ceramics board mounted to the insulated board, aluminum nitride and alumina may also be adapted in addition to silicon nitride. A plurality of ceramics board may also be mounted as required. In this case, silicon nitride board, aluminum nitride board, and alumina board may also be combined as required.

When the semiconductor device of this embodiment as described above is used, thermal stress or strain generated in the manufacturing process or during the operation may be alleviated and possibility of deformation, denaturation and breakdown of each member can also be lowered. Moreover, a highly reliable and low cost semiconductor device having excellent heat radiation property can be provided. In more practical, thermal resistance of 0.4° C./W or less to realize stable electrical operation can be achieved and flatness with less curvature can also be attained by forming the wiring metal board with copper or copper alloy and forming the heat radiating wiring board with a copper-system material having the thermal expansion coefficient which is smaller than that of the wiring metal board. In addition, long-term reliability can also be attained with realization of reduction in the number of solder bonding portions. Moreover, the manufacturing processes can also be simplified and remarkable cost reduction can also be realized through this simplification.

The semiconductor device of the present invention is preferably used as an electronic component of transportation machinery such as vehicles in which importance of heat cycle is considered particularly.

1. A circuit board comprising:
a board including one surface and the other surface opposing to one surface;
a circuit wiring board to mount semiconductor devices provided on one surface of the board; and
a heat radiating wiring board provided on the other surface of the board,
wherein the heat radiating wiring board has a smaller thermal expansion coefficient than the circuit wiring board.

2. The circuit board according to claim 1, wherein the heat radiating wiring board has thermal expansion coefficients which are different in the vertical and horizontal directions within the principal surface, and the longitudinal direction of the board is set almost parallel to the direction showing a smaller thermal expansion coefficient of the heat radiating wiring board.

3. A circuit board comprising:
a board including one surface and the other surface opposing to one surface;
a circuit wiring board to mount semiconductor devices provided on one surface of the board; and
a heat radiating wiring board provided on the other surface of the board,
wherein the circuit wiring board is formed of copper (Cu) or a copper alloy, the heat radiating wiring board is formed of copper (Cu) or a Cu-based element, and the heat radiating wiring board has a smaller thermal expansion coefficient than the circuit wiring board.

4. The circuit board according to claim 3, wherein the heat radiating wiring board has thermal expansion coefficients which are different in the vertical and horizontal directions within the principal surface, and the longitudinal direction of the board is set almost parallel to the direction showing a smaller thermal expansion coefficient of the heat radiating wiring board.

5. The circuit board according to claim 1, wherein the heat radiating and wiring board is formed of a composite metal board in which the Cu₂O powder particles are dispersed into a matrix metal formed of copper (Cu) or a Cu alloy.

6. The circuit board according to claim 1, wherein the board is formed of a ceramics board including at least a kind of material selected from a group of silicon nitride, aluminum nitride, and alumina.

7. The circuit board according to claim 1, wherein the front surfaces of the circuit wiring board and heat radiating wiring board are covered with a corrosion proof metal material.

8. A circuit board comprising:
a board forming one surface and the other surface opposing to the one surface;
a circuit wiring board provided to the one surface of the board for mounting semiconductor devices; and
a peripheral reinforcing board provided to the periphery of the board.

9. The circuit board according to claim 8, wherein both circuit wiring board and peripheral reinforcing board are formed of a similar material.

10. The circuit board according to claim 8 or 9, comprising a heat radiating wiring board provided to the other surface.

11. The circuit board according to claim 10, wherein the heat radiating wiring board has a smaller thermal expansion coefficient than the circuit wiring board.

12. The circuit board according to claim 10, wherein the circuit wiring board is formed of copper (Cu) or a Cu alloy, the heat radiating wiring board is formed of copper (Cu) or a Cu-based element, and the heat radiating wiring board, and the heat radiating wiring board has a smaller thermal expansion coefficient than the circuit wiring board.

13. The circuit board according to claim 10, wherein the heat radiating wiring board has thermal expansion coefficients which are different in the vertical and horizontal directions within the principal surface and the longitudinal direction of the board is almost parallel to the direction having a smaller thermal expansion coefficient of the heat radiating wiring board.

14. A semiconductor device comprising:
the circuit board according to claim 1;
semiconductor elements provided on the circuit wiring board;
a case for storing the circuit board and the semiconductor elements; and
a resin for covering the semiconductor elements and the board stored within the case.

15. A semiconductor device comprising:
the circuit board according to claim 3;
semiconductor elements provided on the circuit wiring board;
a case for storing the circuit board and the semiconductor elements; and
a resin for covering the semiconductor elements and the board stored within the case.

16. A semiconductor device comprising:
the circuit board according to claim 8;
semiconductor elements provided on the circuit wiring board;
a case for storing the circuit board and the semiconductor elements; and
a resin for covering the semiconductor elements and the board stored within the case.

17. A method to form a circuit board comprising the steps of:
preparing for a board;
forming a laminated body by respectively laminating a circuit wiring board to one surface of the board and laminating a heat radiating wiring board to the other surface;
applying heat treatment to the laminated body and brazing the circuit wiring board and the heat radiating wiring board to the board; and
forming a wiring layer by processing the circuit wiring board.

18. The method to form a circuit board according to claim 17, comprising the processes to give the solder bondability and wire bondability to the wiring layer and to implement the process to give the solder bondability to the heat radiating metal board.

19. A method to form a circuit board comprising the steps of:
preparing for a board;
forming a metal layer to one surface of the one surface and the other surface of the board; and
forming a wiring layer to mount semiconductor chips and a peripheral metal layer surround the external circumference of the wiring layer by processing the metal layer.
